(19) United States
(12) Patent Application Publication
(10) Pub. No.: US 2022/0404696 A1
(43) Pub. Date: Dec. 22, 2022

(54) BONDED LAYER ON EXTREME ULTRAVIOLET PLATE

(71) Applicant: ENTEGRIS, INC., Billerica, MA (US)

(72) Inventors: Huaping Wang, Eden Prairie, MN (US); Eric A. Kirkland, Woodland Park, CO (US); Russ V. Raschke, Chanhassen, MN (US)

(21) Appl. No.: 17/842,109

(22) Filed: Jun. 16, 2022

Related U.S. Application Data
(60) Provisional application No. 63/212,270, filed on Jun. 18, 2021.

(51) Int. Cl. G03F 1/66; H01L 21/673

(52) U.S. Cl. CPC G03F 1/66; H01L 21/67359; H01L 21/67366

(57) ABSTRACT

An apparatus includes a reticle pod. The reticle pod includes a baseplate having a first surface, a cover having a second surface, and at least one layer. The first surface includes a first mating surface. The second surface includes a second mating surface. The at least one layer is bonded to one or more of at least a part of the first mating surface and at least a part of the second mating surface. The first surface and the second surface overlap at the first mating surface and the second mating surface when the cover is attached to the baseplate.

### FIELD

This disclosure relates generally to reticle pods used for reticles. More specifically, the disclosure relates to apparatus and method for bonding one or more layers on a baseplate and/or a cover of a reticle pod, such as an extreme ultraviolet (EUV) reticle pod.

### BACKGROUND

Reticle pods are used for containing reticles. Reticles may include, for example, photolithography masks used during semiconductor processing, such as during EUV treatment. Reticle pods can be used for storage and transport of reticles. A reticle pod can include an inner pod that is handled and manipulated by one or more tools during processing. The inner pod of the reticle pod includes a baseplate and a cover. The baseplate and the cover contain the reticle and protect the reticle from contamination or physical damage during transport, storage, and processing. The inner pod can be coated with chromium. Chromium coating may improve the reflectance and appearance of the surface and help to resist losses in reflectance from oxidation. Reticle pods include, for example, EUV pods for use with EUV photolithography tools. Reticle pods can include an outer pod with a pod door and a pod dome, which contains the inner pod.

### SUMMARY

This disclosure relates generally to reticle pods used for reticles. More specifically, the disclosure relates to apparatus and method for bonding one or more layers on a baseplate and/or a cover of a reticle pod such as a EUV reticle pod, etc.

A reticle pod can include an inner pod (e.g., a metal inner pod). The inner pod of the reticle pod can be coated, e.g., with chromium, to improve the reflectance and appearance of the surface and to help resist losses in reflectance from oxidation. The process of polishing, coating, and/or plating the reticle pod can be inconsistent and can allow for potential aesthetic defects. Bonding one or more layers to surface(s) of the reticle pod can allow the reticle pod to forego any secondary polishing, plating, and/or coating.

In an embodiment, an apparatus includes a reticle pod. The reticle pod includes a baseplate having a first surface, a cover having a second surface, and at least one layer. The first surface includes a first mating surface. The second surface includes a second mating surface. The at least one layer is bonded to one or more of at least a part of the first mating surface and at least a part of the second mating surface. The first surface and the second surface overlap at the first mating surface and the second mating surface when the cover is attached to the baseplate.

In an embodiment, the reticle pod is an EUV reticle pod. The baseplate and the cover are configured to accommodate a reticle when the cover is attached to the baseplate.

In an embodiment, the apparatus further includes an outer pod dome and an outer pod door. The outer pod dome and the outer pod door are configured to accommodate the baseplate and the cover within the outer pod dome when the outer pod door is attached to the outer pod dome.

In an embodiment, the at least one layer may comprise glass, graphite, silicon carbide, or ceramic.

In an embodiment, the apparatus further includes a bonding material configured to bond the at least one layer to the one or more of the first mating surface and the second mating surface.

In an embodiment, the bonding material is an adhesive. In an embodiment, the bonding material is epoxy.

In an embodiment, the at least one layer is bonded to the one or more of the first mating surface and the second mating surface by magnetic bonding or heat bonding

In an embodiment, the baseplate and the cover include a substrate. In an embodiment, the substrate is coated with a coating material. In an embodiment, the at least one layer is bonded to the coating material.

In an embodiment, the at least one layer has a predetermined minimum thickness of about 50 microns. In an embodiment, the at least one layer has a predetermined maximum thickness of about one millimeter. In an embodiment, the at least one layer has a predetermined roughness of less than about 0.2 microns roughness average (Ra). In an embodiment, the at least one layer has a predetermined thickness uniformity less than about +/−5 microns.

In an embodiment, the at least one layer includes a first layer and a second layer, the first layer is bonded to at least a part of the first mating surface, the second layer is bonded to at least a part of the second mating surface, and when the cover is attached to the baseplate, the first layer does not overlap with the second layer, a combination of the first layer and the second layer overlaps with an entirety of the first mating surface or an entirety of the second mating surface.

In an embodiment, the first layer is bonded to a half of the first mating surface, and the second layer is bonded to a half of the second mating surface.

In an embodiment, a method of producing a reticle pod is provided. The reticle pod includes a baseplate and a cover. The baseplate has a first surface. The first surface includes a first mating surface. The cover includes a second surface. The second surface includes a second mating surface. The method includes bonding at least one layer to one or more of the first mating surface and the second mating surface.

In an embodiment, the method further includes coating a coating material to a substrate of the baseplate and the cover. Coating is performed before bonding.

In an embodiment, bonding the at least one layer to the one or more of the first mating surface and the second mating surface includes applying a bonding material to bond the at least one layer to the one or more of the first mating surface and the second mating surface.

In an embodiment, bonding the at least one layer to the one or more of the first mating surface and the second mating surface includes magnetic bonding or heat bonding the at least one layer to the one or more of the first mating surface and the second mating surface.

In an embodiment, a material of the at least one layer is glass, graphite, silicon carbide, or ceramic.

### BRIEF DESCRIPTION OF THE DRAWINGS

References are made to the accompanying drawings that form a part of this disclosure and which illustrate the embodiments in which systems and methods described in this specification can be practiced.

FIG. 1A is a cross-sectional view of an inner pod of a reticle pod when closed, according to an embodiment.

FIG. 1B is a cross-sectional view of the inner pod in FIG. 1A when open, according to an embodiment.

FIG. 2 is a top view of a baseplate in a reticle pod, according to an embodiment.

FIG. 3 is a bottom view of a cover for a reticle pod, according to an embodiment.

FIG. 4 is a cross-sectional view of mating surfaces of a baseplate and a cover for a reticle pod, according to an embodiment.

FIG. 5 is a prospective view of a reticle pod, according to an embodiment.

FIG. 6 is a flow chart for a method of producing a reticle pod, according to an embodiment.

Like reference numbers represent like parts throughout.

### DETAILED DESCRIPTION

This disclosure relates generally to reticle pods used for reticles. More specifically, the disclosure relates to apparatus and method for bonding one or more layers on a baseplate and/or a cover of a reticle pod such as a EUV reticle pod, etc.

The following definitions are applicable throughout this disclosure. As defined herein, the term “layer” can refer to a sheet, quantity, and/or thickness of material, typically one of several, covering a surface.

As defined herein, the term “adhesive” can refer to a substance used for joining objects or materials together. In an embodiment, the adhesive can be a layer independent of the objects or materials being joined together.

As defined herein, the term “bonding” can refer to connecting, joining, and/or being joined securely to something else, by means of an adhesive substance, heat processing, pressure processing, and/or magnetic processing, etc.

As defined herein, the term “heat bonding” can refer to a process of bonding objects or materials together by applying heat for connecting or joining the objects or materials. In an embodiment, “heat bonding” can refer to a process that melts objects and/or materials to connect and/or join the objects and/or materials together.

As defined herein, the term “magnetic bonding” can refer to a process of bonding objects or materials together by magnetism of the objects or materials. In an embodiment, “magnetic bonding” can include a process of making one or more of the objects or one or more of the materials (to be connected or joined) permanent magnets. Permanent magnets can include, but are not limited to: neodymium iron boron, samarium cobalt, alnico (e.g., an alloy of aluminum, nickel, and cobalt, etc.), and ceramic or ferrite (e.g., ceramic-like material made from a mix of iron oxides with nickel, strontium, or cobalt, etc.) magnets, etc.

As used herein, the term “about” means within the range a person of skill in the art would consider to be covered by the value. In some embodiments, this is within 10%. In some embodiments, this is reflected by the significant figures provided for the value, e.g., a value of 5 may include values of 4.5 to 5.4 which round to 5, while a value of 5.0 may include values from 4.95 to 5.04.

Particular embodiments of the present disclosure are described herein with reference to the accompanying drawings. However, it is to be understood that the disclosed embodiments are merely examples of the disclosure, which can be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure. In this description, as well as in the drawings, like-referenced numbers represent elements that can perform the same, similar, or equivalent functions.

The scope of the disclosure should be determined by the appended claims and their legal equivalents, rather than by the examples given herein. For example, the steps recited in any method claims can be executed in any order and are not limited to the order presented in the claims. Moreover, no element is essential to the practice of the disclosure unless specifically described herein as “critical” or “essential”.

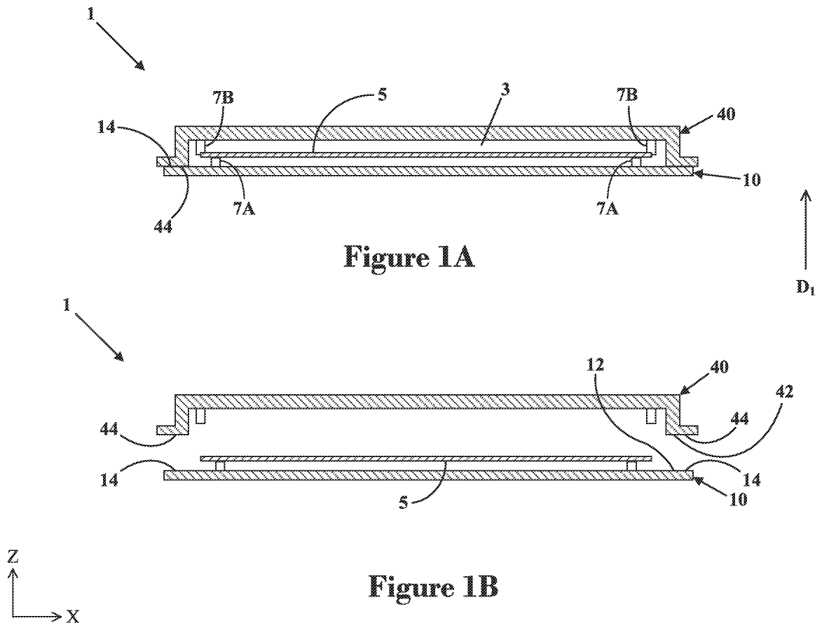

FIGS. 1A and 1B show cross-sectional views an inner pod 1 of a reticle pod, according to an embodiment. FIG. 1A shows the inner pod 1 when closed. FIG. 1B shows the inner pod 1 when open. The inner pod 1 has an internal space with a reticle containment portion 3 for containing a reticle 5. The pod 1 can include reticle supports 7A, 7B within the reticle containment portion 3 for supporting the reticle 5 within the inner pod 1.

The inner pod 1 includes a baseplate 10 and a cover 40. The baseplate 10 and the cover 40 are configured to be joined together. As shown in FIG. 1A, the internal space of the inner pod 1 is enclosed (e.g., closed) by placing the cover 40 on the baseplate 10. The cover 40 directly contacts the baseplate 10. In particular, the bottom 42 of the cover 40 contacts the top 12 of the baseplate 10. The inner pod 1 is opened by moving the cover 40 away from the baseplate 10 (e.g., by moving the cover upwards in direction D₁). For example, an external tool (e.g., an automated arm) opens the inner pod 1 to access the reticle containment portion 3 and remove the reticle 5.

The baseplate 10 and the cover 40 include one or more mating surface(s) that are configured to mate the baseplate 10 and the cover 40 together. In an embodiment, the one or more mating surface(s) can be one or more seal surface(s) that provide sealing between the baseplate 10 and the cover 40. For example, the sealing is configured to reduce or prevent external containments (e.g., air, dust, etc.) from entering the pod 1 by passing between the baseplate 10 and the cover 40. The baseplate 10 can includes one or more mating surfaces that directly contact the cover 40 when the cover 40 is placed on the baseplate 10. The cover 40 includes one or more mating surface configured to directly contact the baseplate 10 when the cover 40 is placed on the baseplate 10. For example, the baseplate 10 can include a first mating surface (e.g., mating surface 14) that is configured to directly contact the cover 40, and the cover 40 can include a second mating surface (e.g., mating surface 44) that is configured to directly contact the baseplate 10.

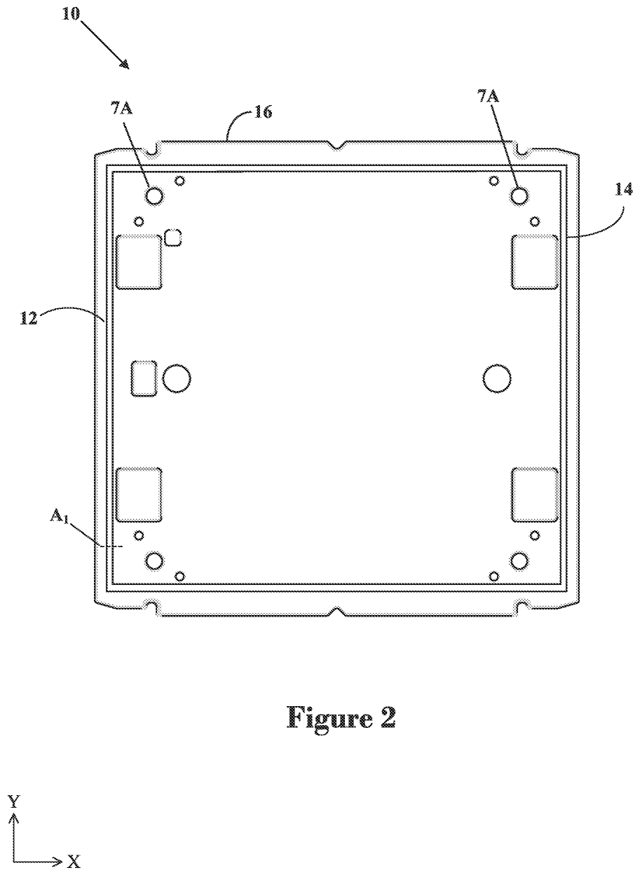

FIG. 2 is a top view of the baseplate 10 for a reticle pod, according to an embodiment. FIG. 2 shows the top 12 of the baseplate 10. The cover 40 is configured to be placed onto the top 12 of the baseplate 10. The baseplate 10 can also include the reticle supports 7A.

The baseplate 10 includes the mating surface 14 and a baseplate body 16. The mating surface 14 is formed on the baseplate body 16. The baseplate 10 in FIG. 2 includes a single continuous mating surface 14. The mating surface 14 extends along the entire perimeter of the baseplate 10. However, the baseplate 10 can include multiple mating surfaces in an embodiment. For example, separate mating surfaces 14 can be provided at locations in which greater amounts of wear occurs between the baseplate 10 and the cover 40. In an embodiment, the mating surface(s) 14 of the baseplate 10 can only extend along a portion of the perimeter of the baseplate 10.

As shown in FIG. 2, the one or more mating surfaces 14 are disposed so as to cover less than 75% of the baseplate 10. In an embodiment, the one or more mating surfaces 14 are disposed so as to cover less than 50% of the baseplate 10. The embodiments described and recited herein are not limited to the quantity described. That is, the quantity described and recited herein are provided for descriptive purposes only and are not intended to be limiting.

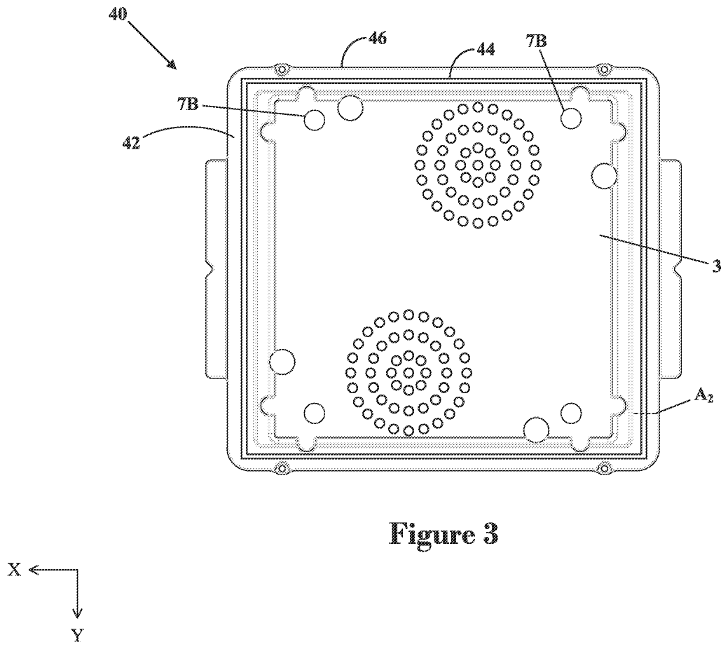

FIG. 3 is a bottom view of the cover 40 for an inner pod, according to an embodiment. FIG. 3 shows the bottom 42 of the cover 40. The bottom 42 of the cover 40 is configured to contact the top 12 of the baseplate 40 when the cover 40 is placed on the baseplate 10. The cover 40 can also include the reticle containment portion 3 and the reticle supports 7B that support the reticle within the inner pod.

The cover 40 includes the mating surface 44 and a cover body 46. The mating surface 44 is formed on the cover body 46. The cover 40 in FIG. 3 includes a single continuous mating surface 44. However, the cover 40 can include multiple mating surfaces in an embodiment. For example, each of the mating surfaces 44 only extending along a portion of the perimeter of the base plate 40. For example, the separate mating surfaces 44 can be provided at locations in which a greater amount of wear occurs between the baseplate 10 and the cover 40.

The mating surface 44 extends along the entire perimeter of the cover 40. Accordingly, when the cover 40 is placed on the baseplate 10, the mating surface 44 is disposed so as to extend along the entire perimeter of the baseplate 10. In some embodiments, the one or more mating surfaces 14 of the baseplate 10 and the one or more mating surfaces 44 of the cover 40 can be disposed so as to extend around the entire perimeter of the baseplate 10 in combination. For example, the mating surface(s) 14 of the baseplate 10 cannot extend along the entire perimeter of the baseplate 10, and the mating surface(s) 44 of the cover 40 extend along the portion(s) of the perimeter of the baseplate 10 without the mating surface(s) 14. When considered in combination, the mating surface(s) 14 of the baseplate 10 and the mating surfaces 44 of the cover 40 would extend along the entire perimeter of the baseplate 10.

The mating surface(s) 44 are provided so as to cover less than 75% of the cover 40. In an embodiment, the mating surface(s) 44 cover less than 50% of the cover 40. The mating surface(s) 14, 44 of the inner pod 1 are formed so as to cover less than 75% of the baseplate 10 and the cover 40. In an embodiment, the mating surface(s) 14, 44 are formed so as to cover less than 50% of the baseplate 10 and the cover 40. The embodiments described and recited herein are not limited to the quantity described. That is, the quantity described and recited herein are provided for descriptive purposes only and are not intended to be limiting.

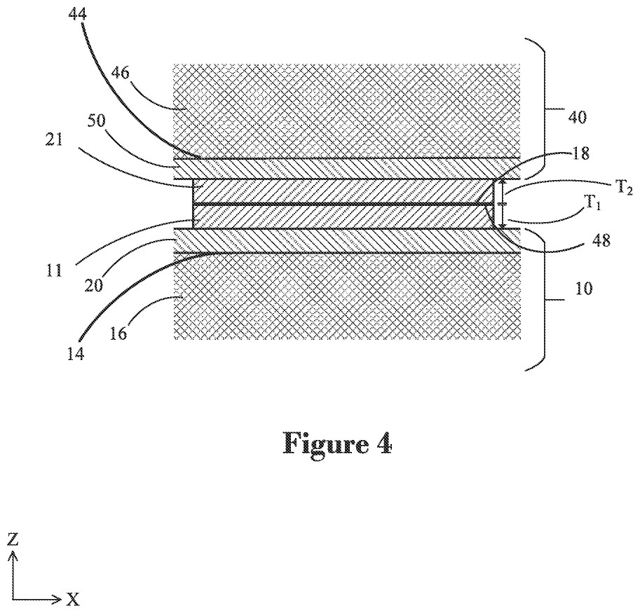

FIG. 4 is a cross-sectional view across the mating surfaces 14, 44 of the baseplate 10 and the cover 40, according to an embodiment. For example, the cross-section in FIG. 4 extends through the dashed line A₁ in FIG. 2 and the dashed line A₂ in FIG. 3. FIG. 4 shows a structure and interaction of a mating surfaces 14, 44 when the cover 40 is placed on the baseplate 10 (e.g., as shown in FIG. 1B).

It will be appreciated that in some embodiments, only one of the baseplate 10 and the cover 40 can have mating surface(s). For example, the cover 40 can be provided with one or more mating surfaces 44 while the baseplate 10 does not include any mating surfaces, or vice-versa.

The mating surface 14 is formed on the baseplate body 16, and the mating surface 44 is formed on the cover body 46. In an embodiment, the baseplate body 16 and the cover body 46 are respectively formed of metal or any other suitable material. In an embodiment, the baseplate body 16 and the cover body 46 can be formed of the same metal. In an embodiment, the baseplate body 16 includes a substrate (e.g., aluminum, nickel, stainless steel, or any other suitable material) and the mating surface 14 is formed on the substrate of the baseplate body 16. In an embodiment, the cover body 46 includes a substrate (e.g., aluminum, nickel, stainless steel, or any other suitable material) and the mating surface 44 is formed on the substrate of the cover body 46. In an embodiment, the baseplate body 16 and the cover body 46 can be formed of different materials.

In an embodiment, the mating surface 14 can be formed of the same material as the substrate of the baseplate body 16. The mating surface 44 can be formed of the same material as the substrate of the cover body 46. In an embodiment, a chromium coating, a nickel coating, a plasma coating, or any other suitable coating can be applied to the substrate of the baseplate body 16, the substrate of the cover body 46, the mating surface 14, and/or the mating surface 44, to apply chromium, nickel, plasma, or the like as coating to the surface(s) of the baseplate body 16, the substrate of the cover body 46, the mating surface 14, and/or the mating surface 44.

For example, as shown in FIG. 4, a coating layer 20 can be formed on the baseplate body 16 and/or the mating surface 14. The coating layer 20 can be, but is not limited to, nickel, chromium, plasma, etc. In an embodiment, a plurality of coating layers 20 (e.g., about three layers with e.g., chromium as final or top layer, the layers can be formed of nickel and/or chromium and/or plasma and have thickness of about 25 micron) can be provided on the baseplate body 16 and/or the mating surface 14. The coating layer(s) 20 can improve one or more properties of the baseplate 10 (e.g., decreased reactivity, increased strength, etc.). In an embodiment, the cover 40 (the cover body 46 and/or the mating surface 14) can include a coating layer 50 in a similar manner as described above for the coating layer 20.

In an embodiment, the mating surfaces 14, 44 can have a coating which is different from the coating to the substrate of the baseplate body 16 and/or the substrate of the cover body 46. For example, each mating surface 14, 44 can include a coating, and the coating can be, but is not limited to, titanium nitride, chromium nitride, and/or diamond-like carbon (DLC), or the like. It will be appreciated that different embodiments of such coatings of the mating surfaces 14, 44 are described in U.S. Application No. 63/017,825, which is hereby incorporated by reference in its entirely.

As shown in FIG. 4, a layer 11 can be bonded to the mating surface 14 of the baseplate 10 after the baseplate 10 is coated with e.g., the coating layer(s) 20. A layer 21 can be bonded to the mating surface 44 of the cover 40 after the cover 40 is coated with e.g., the coating layer(s) 50. In another embodiment, only layer 11 is bonded to the mating surface 14, and the layer 21 is optional. In yet an embodiment, only layer 21 is bonded to the mating surface 44, and the layer 11 is optional. In FIGS. 1A-4, the baseplate 10 and the cover 40 are provided with at least one bonding layer(s) 11, 21. The bonding layer 11 of the coated baseplate 10 directly contacts the bonding layer 21 of the coated cover 40 when the coated cover 40 having the bonding layer 21 is placed on the coated baseplate 10 having the bonding layer 11. In other embodiments, a layer 11, 21 cannot contact the bonding layer of an opposing coated mating surface. The layer(s) 11, 21 can directly contact the opposing coated mating surface. For example, the layer 11 can directly contact the coated cover 40 when the coated cover 40 is placed on the coated baseplate 10 having the bonding layer 11. In another embodiment, the layer 11 can be bonded to the mating surface 14 of the baseplate 10 and the baseplate 10 is not coated with a coating layer. The layer 21 can be bonded to the mating surface 44 of the cover 40 and the cover 40 is not coated with a coating layer.

In an embodiment, the layer 11 can be bonded to at least a part of the mating surface 14. The layer 21 can be bonded to at least a part of the mating surface 44. When the cover 40 is attached to the baseplate 10, the layer 11 does not overlap with the layer 21, and a combination of the layer 11 and the layer 21 overlaps with an entirety of the mating surface 14 or an entirety of the mating surface 44.

For example, the layer 11 can be bonded to a half of the mating surface 14, and the layer 21 can be bonded to a half of the mating surface 44. When the cover 40 is attached to the baseplate 10, the layer 11 does not overlap with the layer 21, but a combination of the layer 11 and/or the layer 21 overlaps with an entirety of the mating surface 14 or an entirety of the mating surface 44. It will be appreciated that the layer 11 can be bonded to any suitable portion(s) or division(s) or segment(s) of the mating surface 14, and the layer 21 can be bonded to any suitable portion(s) or division(s) or segment(s) of the mating surface 44. In such embodiment, a combination of the layer 11 and the layer 21 can overlap with an entirety of the mating surface 14 or an entirety of the mating surface 44 to provide proper sealing.

In an embodiment, the layer(s) 11, 21 can be bonding layer(s) formed of glass, graphite, silicon carbide (SiC), ceramic, or any other suitable material(s). The layer 11 has a thickness T₁. The layer 21 has a thickness T₂. In an embodiment, each of the thickness T₁, T₂ can have a minimum thickness of about 50 microns. It will be appreciated that the minimum thickness can aid ease of handling of the layer. Each of the thickness T₁, T₂ can have a maximum thickness of about one millimeter. It will be appreciated that the maximum thickness can aid ease of manufacturing of the layer and maintain uniform thickness of the layer. Each of the thickness T₁, T₂ can have a roughness of less than about 0.2 microns roughness average (Ra). It will be appreciated that the roughness can improve wear performance, reduce particle hiding, improve sealing performance, and/or maintain proper coefficient of friction. Each of the thickness T₁, T₂ can have a thickness uniformity less than about +/−5 microns. It will be appreciated that the thickness uniformity can help proper surface flatness and/or improve sealing performance.

Each layer 11, 21 may extend along the entire length of its coated mating surface 14, 44. For example, the layer 11 can extend along the entire perimeter of the baseplate 10 as similarly described above and shown in FIG. 2 for the mating surface 14.

Returning to FIG. 4, along each coated mating surface 14 of the baseplate 10, a layer 11 provides the overlapping surface 18 of the baseplate 10. Along each coated mating surface 44 of the cover 40, the layer 21 provides the overlapping surface 48 of the cover 40. Accordingly, the cover 40 when placed on the baseplate 10 only contacts the baseplate 10 via one or more of the overlapping surfaces 18, 48.

In an embodiment, the layers 11, 21 can be bonded to the coated mating surfaces 14, 44 via heat bonding, pressure bonding (e.g., pressure sensitive adhesives, etc.), magnetic bonding, mechanical bonding (e.g., mechanical interlocking, etc.), actinic radiation curing adhesives, light-curing adhesives, or any other suitable bonding process without requiring a bonding material between the layers 11, 21 and the respective coated mating surfaces 14, 44.

In an embodiment, the layers 11, 21 can be bonded to the respective coated mating surfaces 14, 44 by applying a bonding material (not shown) between the layers 11, 21 and the coated mating surfaces 14, 44. The bonding material can be a layer configured to bond the layers 11, 21 to the coated mating surfaces 14, 44. In an embodiment, the bonding material can be an adhesive or any other suitable material. In an embodiment, the bonding material can be epoxy, pressure sensitive adhesive, or any other suitable material.

It will be appreciated that bonding the layers 11, 21 to the coated baseplate 10 and/or the coated cover 40 can allow the baseplate 10 and/or the cover 40 to forego any secondary polishing, plating, or coating. The layers 11, 21 can have a more consistent surface quality than the coated baseplate 10 and/or the coated cover 40 and can reduce wear damage of the coated baseplate 10 and/or the coated cover 40. The layers 11, 21 can be premanufactured, thin, flat, solid, and/or smooth, and formed of, e.g., wear resistant materials. It will be appreciated that a smoother surface (e.g., the overlapping surface(s) 18, 48) of the bonding layer can provide a better wear-resistance. Bonding the layer(s) 11, 21 to the coated baseplate 10 and/or the coated cover 40 can help control aesthetic issues and/or reduce yield losses. The properties of the layer(s) 11, 21 (to be bonded to the baseplate 10 and/or the cover 40) can ensure ease of handling of the layer(s), ensure ease of manufacturing of the layer(s), maintain uniform thickness of the layer(s), improve wear performance, reduce particle hiding, maintain proper coefficient of friction, ensure proper surface flatness, and/or improve sealing performance.

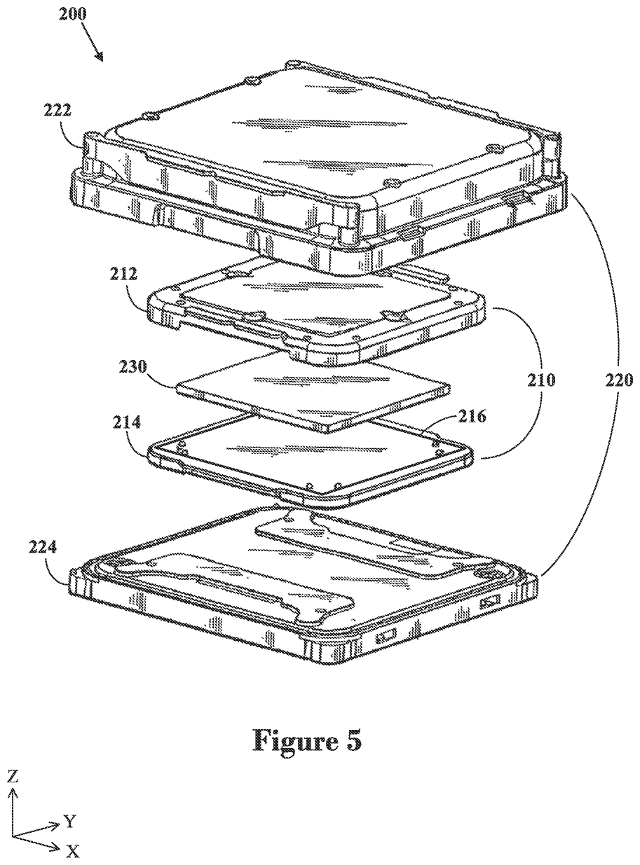

FIG. 5 is a prospective view of a reticle pod 200, according to an embodiment. The reticle pod 200 includes an inner pod 210 and an outer pod 220. For example, the reticle pod 200 can be, but is not limited to, a reticle pod for EUV processing of photolithography masks, or the like. In an embodiment, the inner pod 210 has a length of about 8 inches and a width of about 8 inches.

The inner pod 210 includes a cover 212 and a baseplate 214. The cover 212 and the baseplate 214 are configured to be joined together. When joined together, the cover 212 and the baseplate 214 define an internal space sized and shaped contain a reticle 230. For example, the reticle 230 can be, but is not limited to, a photolithography mask that will be used in EUV processing, etc. In some embodiments, at least one of the cover 212 and the baseplate 214 include one or more bonding layers 216 as similarly discussed above for the baseplate 10 and cover 40 in FIGS. 1A-4. In some embodiments, the cover 212 and the baseplate 214 each include at least one of the bonding layers 216 (obscured in FIG. 5 for the cover 212). The cover 212 can be, for example, the cover 40 described above and shown in FIGS. 1A, 1B, and 3. The baseplate 214 can be, for example, the baseplate 10 described above and shown in FIGS. 1A, 1B, and 2.

The outer pod 220 includes an outer pod dome 222 and an outer pod door 224. The outer pod 220 is configured to accommodate the inner pod 210 within an internal space defined by the outer pod dome 222 and the outer pod door 224. The outer pod dome 222 can be secured to the outer pod door 224 to enclose the internal space and contain the inner pod 210, for example during transport and handling of the reticle pod 200. The outer pod dome 222 and the outer pod door 224 can each include or be made entirely of one or more polymer materials or any other suitable materials.

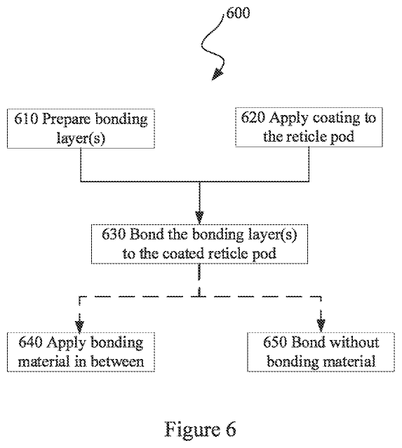

FIG. 6 is a flow chart for a method 600 of producing a reticle pod, according to an embodiment. For example, the method 600 can form reticle pod 200 as described above and in FIG. 5, or form one or both of the baseplate 10 and the cover 40 for a reticle pod described above and in FIGS. 1A-4. In an embodiment, the reticle pod is a EUV reticle pod.

The operational or processing flow chart 600 can include one or more operations, actions, or functions depicted by one or more blocks 610, 620, 630, 640, and 650. Although illustrated as discrete blocks, various blocks can be divided into additional blocks, combined into fewer blocks, or eliminated, depending on the desired implementation. The method 600 can start at either block 610 or block 620. It will be appreciated that block 610 can precede block 620, or vice versa.

At 610, a bonding layer (e.g., layer 11 and/or layer 21) is prepared, provided, and/or manufactured. At 620, a reticle pod including a baseplate (e.g., baseplate 10, baseplate 214), a cover (e.g., cover 40, cover 212), and/or mating surfaces (e.g., mating surface(s) 14 and 44) is provided. In an embodiment, 620 can include forming one or both of the baseplate and the cover. At 620, one or more mating surfaces (e.g., mating surface 14, mating surface 44, mating surface 216) are formed on at least one of a baseplate body of the baseplate (e.g., baseplate body 16) and a cover body of the cover (e.g., cover body 46). The one or more mating surfaces are configured to e.g., provide sealing between the baseplate and the cover. At 620, the reticle pod is coated by e.g., a chromium coating, a nickel coating, a plasma coating, or any other suitable coating. The method 600 then proceeds to 630.

At 630, the bonding layer(s) 11, 21 can be bonded to the reticle pod. In an embodiment, only the layer 11 is bonded to the coated mating surface 14 of the baseplate 10. In an embodiment, only the layer 21 is bonded to the coated mating surface 44 of the cover 40. In an embodiment, the layer 11 is bonded to the coated mating surface 14 of the baseplate 10, and the layer 21 is bonded to the coated mating surface 44 of the cover 40. The method 600 then proceeds to either 640 or 650.

At 640, a bonding material can be applied between the bonding layer(s) 11, 21 and the coated mating surface(s) 14, 44 to bond the bonding layer(s) 11, 21 to the coated mating surface(s) 14, 44. The bonding material can be adhesive, epoxy, or any other suitable material that can bond the bonding layer(s) 11, 21 to the coated mating surface(s) 14, 44.

At 650, heat bonding, pressure bonding, magnetic bonding, mechanical bonding, and/or any other suitable bonding process without requiring a bonding material between the layer(s) 11, 21 and the coated mating surface(s) 14, 44 can be applied to bond the bonding layer(s) 11, 21 to the coated mating surface(s) 14, 44.

It should be appreciated that the method 600 in various embodiments can be modified to achieve feature(s) comparable to those discussed above with respect to the baseplate 10 and cover 40 in FIGS. 1A-4. For example, the method 600 in an embodiment can form the one or more mating surfaces so as to extend along an entire perimeter of the baseplate.

Embodiments disclosed herein can improve wear performance of the reticle pod and thus improve the longevity and/or yield of the reticle pod. The described features may mitigate defects (e.g., bumps that could wear prematurely overtime) and/or the irregularities and/or inconsistencies.

### Aspects

Any of aspects 1-17 can be combined with any of aspects 18-22.

Aspect 1. An apparatus comprising a reticle pod, the reticle pod having: a baseplate having a first surface, the first surface including a first mating surface; a cover having a second surface, the second surface including a second mating surface; and a bonded layer bonded to the first mating surface or the second mating surface, wherein the first surface and the second surface overlap at the first mating surface and the second mating surface when the cover is attached to the baseplate.

Aspect 2. The apparatus of aspect 1, wherein the reticle pod is an Extreme Ultraviolet (EUV) reticle pod, and the baseplate and the cover are configured to accommodate a reticle when the cover is attached to the baseplate.

Aspect 3. The apparatus of aspect 1 or aspect 2, further comprising an outer pod dome and an outer pod door, the outer pod dome and the outer pod door configured to accommodate the baseplate and the cover within the outer pod dome when the outer pod door is attached to the outer pod dome.

Aspect 4. The apparatus of any one of aspects 1-3, wherein a material of the bonded layer is glass, graphite, silicon carbide, or ceramic.

Aspect 5. The apparatus of any one of aspects 1-4, further comprising a bonding material configured to bond the bonded layer to the first mating surface or the second mating surface.

Aspect 6. The apparatus of aspect 5, wherein the bonding material is an adhesive.

Aspect 7. The apparatus of aspect 5, wherein the bonding material is an epoxy.

Aspect 8. The apparatus of any one of aspects 1-7, wherein the bonded layer is bonded to the first mating surface or the second mating surface by magnetic bonding or heat bonding.

Aspect 9. The apparatus of any one of aspects 1-8, wherein the baseplate and the cover include a substrate.

Aspect 10. The apparatus of aspect 9, wherein the substrate is coated with a coating material.

Aspect 11. The apparatus of aspect 10, wherein the bonded layer is bonded to the coating material.

Aspect 12. The apparatus of any one of aspects 1-11, wherein the bonded layer has a predetermined minimum thickness of about 50 microns.

Aspect 13. The apparatus of any one of aspects 1-12, wherein the bonded layer has a predetermined maximum thickness of about one millimeter.

Aspect 14. The apparatus of any one of aspects 1-13, wherein the bonded layer has a predetermined roughness of less than about 0.2 microns roughness average.

Aspect 15. The apparatus of any one of aspects 1-14, wherein the bonded layer has a predetermined thickness uniformity less than about +/−5 microns.

Aspect 16. The apparatus of any one of aspects 1-15, wherein the bonded layer is a first bonded layer and is bonded to the first mating surface and further comprising a second bonded layer bonded to the second mating surface, and when the cover is attached to the baseplate, the first bonded layer does not overlap with the second bonded layer.

Aspect 17. The apparatus of aspect 16, wherein the first bonded layer is bonded to a half of the first mating surface and the second bonded layer is bonded to a half of the second mating surface.

Aspect 18. A method of producing a reticle pod, the reticle pod including a baseplate and a cover, the baseplate having a first surface, the first surface including a first mating surface, the cover including a second surface, and the second surface including a second mating surface, the method comprising: bonding at least one layer to one or more of the first mating surface and the second mating surface.

Aspect 19. The method of aspect 18, further comprising: coating a coating material to a substrate of the baseplate and the cover, wherein coating is performed before bonding.

Aspect 20. The method of aspect 18 or aspect 19, wherein bonding the at least one layer to the one or more of the first mating surface and the second mating surface includes applying a bonding material to bond the at least one layer to the one or more of the first mating surface and the second mating surface.

Aspect 21. The method of any one of aspects 18-20, wherein bonding the at least one layer to the one or more of the first mating surface and the second mating surface includes magnetic bonding or heat bonding the at least one layer to the one or more of the first mating surface and the second mating surface.

Aspect 22. The method of any one of aspects 18-21, wherein a material of the at least one layer is glass, graphite, silicon carbide, or ceramic.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes can be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. An apparatus comprising a reticle pod, the reticle pod having:
a baseplate having a first surface, the first surface including a first mating surface;
a cover having a second surface, the second surface including a second mating surface; and
a bonded layer bonded to one of the first mating surface and the second mating surface,
wherein the first surface and the second surface overlap at the first mating surface and the second mating surface when the cover is attached to the baseplate.

2. The apparatus of claim 1, wherein the reticle pod is an Extreme Ultraviolet (EUV) reticle pod, and
the baseplate and the cover are configured to accommodate a reticle when the cover is attached to the baseplate.

3. The apparatus of claim 1, further comprising an outer pod dome and an outer pod door, the outer pod dome and the outer pod door configured to accommodate the baseplate and the cover within the outer pod dome when the outer pod door is attached to the outer pod dome.

4. The apparatus of claim 1, wherein a material of the bonded layer is glass, graphite, silicon carbide, or ceramic.

5. The apparatus of claim 1, further comprising a bonding material configured to bond the bonded layer to the first mating surface or the second mating surface.

6. The apparatus of claim 5, wherein the bonding material is an adhesive.

7. The apparatus of claim 5, wherein the bonding material is an epoxy.

8. The apparatus of claim 1, wherein the bonded layer is bonded to the first mating surface or the second mating surface by magnetic bonding or heat bonding.

9. The apparatus of claim 1, wherein the baseplate and the cover include a substrate.

10. The apparatus of claim 9, wherein the substrate is coated with a coating material.

11. The apparatus of claim 10, wherein the bonded layer is bonded to the coating material.

12. The apparatus of claim 1, wherein the bonded layer has a thickness of about 50 microns to about one millimeter.

13. The apparatus of claim 1, wherein the bonded layer has a predetermined roughness of less than about 0.2 microns roughness average.

14. The apparatus of claim 1, wherein the bonded layer has a predetermined thickness uniformity less than about +/−5 microns.

15. The apparatus of claim 1, wherein the bonded layer is a first bonded layer bonded to the first mating surface and further comprising a second bonded layer bonded to the second mating surface, and
when the cover is attached to the baseplate, the first bonded layer does not overlap with the second bonded layer.

16. The apparatus of claim 15, wherein the first bonded layer is bonded to a half of the first mating surface and the second bonded layer is bonded to a half of the second mating surface.

17. A method of producing a reticle pod, the reticle pod including a baseplate and a cover, the baseplate having a first surface, the first surface including a first mating surface, the cover including a second surface, and the second surface including a second mating surface, the method comprising:
bonding at least one layer to one or more of the first mating surface and the second mating surface.

18. The method of claim 17, further comprising:
coating a coating material to a substrate of the baseplate and the cover,
wherein coating is performed before bonding.

19. The method of claim 17, wherein bonding the at least one layer to the one or more of the first mating surface and the second mating surface includes applying a bonding material to bond the at least one layer to the one or more of the first mating surface and the second mating surface.

20. The method of claim 17, wherein bonding the at least one layer to the one or more of the first mating surface and the second mating surface includes magnetic bonding or heat bonding the at least one layer to the one or more of the first mating surface and the second mating surface.
